(19) United States
(12) Patent Application Publication
(10) Pub. No.: US 2008/0158220 A1
(43) Pub. Date: Jul. 3, 2008

(54) Power-on-reset circuit and method therefor

(75) Inventors: Chung-Ming Huang, Sinshih Township (TW); Chih-Haur Huang, Sinshih Township (TW)

Correspondence Address: RABIN & Berdo, PC, 1101 14TH STREET, NW, SUITE 500, WASHINGTON, DC, 20005, US

(73) Assignee: HIMAX TECHNOLOGIES LIMITED, Township (TW)

(21) Appl. No.: 11/648,548

(22) Filed: Jan. 3, 2007

(51) Int. Cl. G09G 5/00; H03L 7/00

(52) U.S. Cl. 345/213; 327/143

(57) ABSTRACT

A power-on-reset circuit used to detect a first supply voltage for resetting a semiconductor device within an electric system is provided. The power-on-reset circuit is equipped with the first supply voltage to power the semiconductor device and a second supply voltage generated prior to the first supply voltage. The power-on-reset circuit includes a voltage divider, a bandgap reference circuit and a comparator. The voltage divider is powered by the first supply voltage to generate a proportional input voltage. The bandgap reference circuit is powered by the second supply voltage to generate a constant reference voltage. The comparator compares the proportional input voltage with the constant reference voltage, so as to generate a power-on-reset signal when the proportional input voltage exceeds the constant reference voltage. Therefore, when the first supply voltage is sufficiently large, the power-on-reset circuit can correctly reset the electric system.

### BACKGROUND OF THE INVENTION

1. Field of the Invention

The invention relates in general to a power-on-reset circuit, and more particularly to a power-on-reset circuit applicable to low-voltage operations.

2. Description of the Related Art

FIG. 1 is a block diagram of a conventional power-on-reset circuit. The power-on-reset circuit 100 is provided to reset a semiconductor device such as a timing controller within an electric system such as an LCD system according to detection of an supply voltage Vp. When the supply voltage Vp is sufficiently large, the power-on-reset circuit 100 may output a high-level power-on-reset voltage Vo to reset the semiconductor device, otherwise, the power-on-reset circuit 100 may output a low-level power-on-reset voltage Vo to keep the semiconductor device disabled.

The power-on-reset circuit 100 in FIG. 1 includes a bandgap reference circuit 110, a voltage divider 120 and a comparator 130. Both the bandgap reference circuits 110 and the voltage divider 120 are powered by the same supply voltage Vp so as to respectively output a constant reference voltage Vr and an input voltage Vi proportional to the supply voltage Vp (or a proportional input voltage Vi) as two inputs to the comparator 130. The comparator 130 then compares the constant reference voltage Vr and the proportional input voltage Vi to output an high-level power-on-reset voltage Vo when the proportional input voltage Vi exceeds the constant reference voltage Vr.

However, the constant reference voltage Vr may not be prepared promptly by the bandgap reference circuit 110 unless the supply voltage Vp is sufficiently large. In this case, the comparator 130 may incorrectly compare the proportional input voltage Vi with an unexpected reference voltage Vr. Therefore, the conventional power-on-reset circuit is not applicable to low-voltage operations.

### SUMMARY OF THE INVENTION

It is an object of the invention to provide a power-on-reset circuit to reset a semiconductor device within an electric system correctly even when the first supply voltage to power the semiconductor device is not sufficiently large. By sequentially providing a second supply voltage and the first supply voltage to power the bandgap reference circuit and the voltage divider within the power-on-reset circuit, the constant reference voltage may be promptly prepared using the second supply voltage by the time the first supply voltage is generated. Therefore, the comparator may correctly compare the proportional input voltage generated by the voltage divider with the constant reference voltage.

The invention provides a power-on-reset circuit for a semiconductor device within an electric system equipped with a first supply voltage to power the semiconductor device and a second supply voltage generated prior to the first supply voltage. The power-on-reset circuit includes a voltage divider, a bandgap reference circuit, and a comparator. The voltage divider is powered by the first supply voltage to generate a proportional input voltage. The bandgap reference circuit is powered by the second supply voltage to generate a constant reference voltage. The comparator then compares the proportional input voltage with the constant reference voltage to generate a power-on-reset signal when the proportional input voltage exceeds the constant reference voltage.

The invention provides a method for generating a power-on-reset signal to reset a semiconductor device within an electric system, wherein the electric system is equipped with a first supply voltage to power the semiconductor device and a second supply voltage generated prior to the first supply voltage. The method includes, first, generating a constant reference voltage according to the second supply voltage; then, generating a proportional input voltage according to the first supply voltage; and, comparing the proportional input voltage and the constant reference voltage to generate a power-on-reset signal when the proportional input voltage exceeds the constant reference voltage.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a block diagram of a conventional power-on-reset circuit;

FIG. 2 is a block diagram of a power-on-reset circuit according to an embodiment of the invention;

FIG. 3 is a timing diagram of a first supply voltage, a second supply voltage, a constant reference voltage, a proportional input voltage and a power-on-reset signal according to an embodiment of the invention; and

FIG. 4 is a method for generating a power-on-reset signal according to an embodiment of the invention.

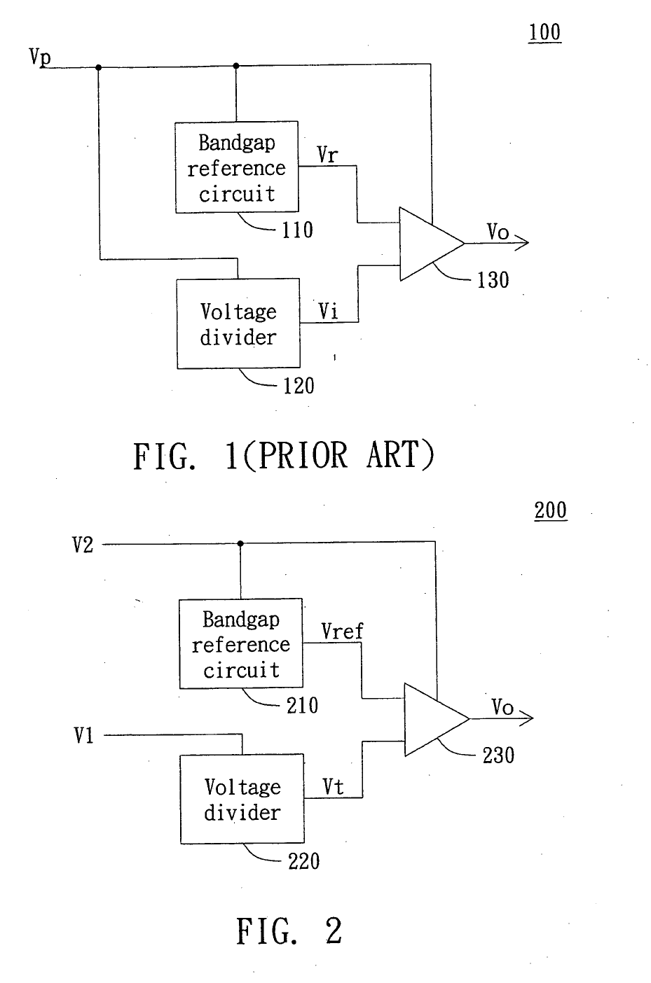

### DETAILED DESCRIPTION OF THE INVENTION

The power-on-reset circuit according to an embodiment of the invention is provided to detect a first supply voltage, so as to output a power-on-reset voltage to reset a semiconductor device within an electric system even when the first supply voltage is not sufficiently large. The voltage divider and the bandgap reference circuit of the power-on-reset circuit according to the embodiment of the invention are respectively powered by the first supply voltage and a second supply voltage generated prior to the first supply voltage. Consequently, the constant reference voltage can be promptly prepared by the time the first supply voltage is generated, and the comparator can correctly compare the proportional input voltage with the constant reference voltage to determine whether the first supply voltage is sufficiently large. When the first supply voltage is determined to be sufficiently large by the power-on-reset circuit, the comparator may output the power-on-reset voltage to reset the semiconductor within the electric system.

FIG. 2 is a block diagram of a power-on-reset circuit according to an embodiment of the invention. The power-on-reset circuit 200 of FIG. 2 is used to reset a semiconductor device such as a timing controller within an electric system such as an LCD system. The electric system is equipped with a first supply voltage V1 to power the semiconductor device and a second supply voltage V2 generated prior to the first supply voltage V1. The power-on-reset circuit 200 receives and detects the first supply voltage V1, and also receives the second voltage voltage V2.

The power-on-reset circuit 200 includes a bandgap reference circuit 210, a voltage divider 220 and a comparator 230. The voltage divider 220 and the bandgap reference circuit 210 are respectively powered by the first supply voltage V1 and the second supply voltage V2. The second supply voltage V2 is generated prior to the first supply voltage V1, such that the bandgap reference circuit 210 can promptly prepare a constant reference voltage Vref by the time the first supply voltage V1 is generated. That is, by the time when the proportional input voltage Vt is prepared by the voltage divider 220, the reference voltage Vref is already prepared.

The comparator 230 then compares the proportional input voltage Vt with the constant reference voltage Vref so as to determine whether the first supply voltage V1 is sufficiently large. When the first supply voltage V1 is sufficiently large, i.e., when the proportional input voltage Vt exceeds the constant reference voltage Vref, the comparator 230 outputs a power-on-reset signal Vo to reset the semiconductor device within the electric system.

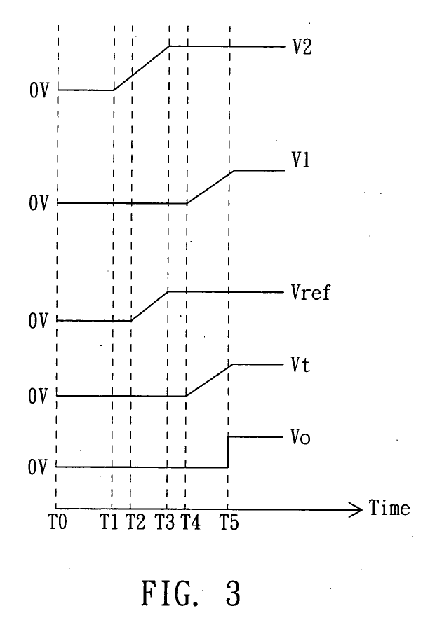

FIG. 3 is a timing diagram of a first supply voltage, a second supply voltage; a constant reference voltage, a proportional input voltage and a power-on-reset signal according to an embodiment of the invention. The operation of the power-on-reset circuit 200 is further elaborated by reference to FIG. 3. At time T0, the semiconductor device within the electric system is disabled, and all the stated voltages are at their initial state, which is 0V in the present embodiment of the invention. At time T1, when the semiconductor device system is reset, the second supply voltage V2 begins to raise, and the bandgap reference circuit 210 is able to prepare the constant reference voltage Vref accordingly.

After the constant reference voltage Vref is prepared at time T3, at time T4, the first supply voltage V1 begins to raise, and the proportional input voltage Vt is able to be generated by the voltage divider 220 accordingly.

Thus, the constant reference voltage Vr may be promptly prepared by the time the first supply voltage V1 is generated. The constant reference voltage Vr and the proportional input voltage Vt are continuously compared. Before time T5, as the first supply voltage V1 is not sufficiently large, i.e., the comparator 230 compares and determines that the proportional input voltage Vt is smaller than the constant reference voltage Vref, a low-level power-on-reset signal Vo is output to keep the semiconductor device disable. When the first supply voltage V1 continues to raise and the proportional input voltage Vt exceeds the constant reference voltage Vref at time T5, the comparator 230 will output a high-level power-on-reset signal Vo to reset the semiconductor device.

In the power-on-reset circuit according to the embodiment of the invention, the bandgap reference circuit and the voltage divider are respectively powered by the second supply voltage and the first supply voltage, wherein the second supply voltage is generated prior to the first supply voltage. Consequently, by the time the first supply voltage is generated, the constant reference voltage is already prepared, such that the proportional input voltage and the constant reference voltage may be correctly compared. Therefore, even when the power-on-reset circuit according to the embodiment of the invention is used to reset a semiconductor device within an electric system operated at a low voltage, the bandgap reference circuit will still generate the power-on-reset signal correctly.

Besides, to ensure prompt reaction of the comparator 230, it is preferable that the comparator 230 is also powered by the second supply voltage. Further, for the constant reference voltage to be prepared even earlier, the second supply voltage may also exceed the first supply voltage when the semiconductor device is reset.

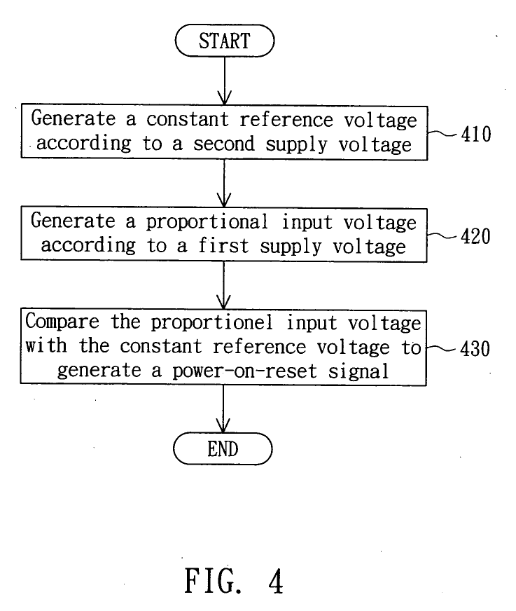

FIG. 4 illustrates a method for generating a power-on-reset signal according to an embodiment of the invention used in the power-on-reset circuit 200 for resetting a semiconductor device within an electric system. Firstly, at step 410, the constant reference voltage is generated by the bandgap reference circuit according to the second supply voltage generated prior to the first supply voltage. Next, at step 420, the proportional input voltage is generated by the voltage divider according to the first supply voltage. Then, at step 430, the comparator compares the constant reference voltage with the proportional input voltage, so as to output a power-on-reset signal to reset the semiconductor device within the electric system when the proportional input voltage exceeds the constant reference voltage.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A power-on-reset circuit for a timing controller within an LCD (Liquid Crystal Display) system that generates a first supply voltage to power the timing controller and generates a second supply voltage prior to generating the first supply voltage, comprising:
a voltage divider powered by the first supply voltage to generate a proportional input voltage;
a bandgap reference circuit powered by the second supply voltage to generate a constant reference voltage; and
a comparator for comparing the proportional input voltage with the constant reference voltage, so as accordingly to output a power-on-reset signal to the timing controller and reset the timing controller when the proportional input voltage exceeds the constant reference voltage.

2. The power-on-reset circuit according to claim 1, wherein the power-on-reset signal is of a high level when the proportional input voltage exceeds the constant reference voltage.

3. The power-on-reset circuit according to claim 1, wherein the power-on-reset signal is of a low level when the proportional input voltage does not exceed the constant reference voltage.

4. The power-on-reset circuit system according to claim 1, wherein the comparator is powered by the second supply voltage.

5. The power-on-reset circuit system according to claim 1, wherein the second supply voltage is higher than the first supply voltage when the timing controller is reset.

6. (canceled)

7. A method for generating a power-on-reset signal to reset a timing controller within an LCD system, wherein the LCD system generates a first supply voltage to power the timing controller and generates a second supply voltage prior to generating the first supply voltage, the method comprising:
generating a constant reference voltage according to the second supply voltage by a voltage divider;
generating a proportional input voltage according to the first supply voltage by a bandgap reference circuit;
comparing the proportional input voltage with the constant reference voltage accordingly to output a power-on-reset signal to the timing controller and reset the timing controller when the proportional input voltage exceeds the constant reference voltage.

8. The method according to claim 7, wherein the power-on-reset signal is of a high level when the proportional input voltage exceeds the constant reference voltage.

9. The method according to claim 7, wherein the power-on-reset signal is of a low level when the proportional input voltage does not exceed the constant reference voltage.

10. The method according to claim 7, wherein the second supply voltage is higher than first supply voltage when the timing controller is reset.

11. A system, comprising:
a timing controller for an LCD system that generates a first supply voltage to power the timing controller and generates a second supply voltage prior to generating the first supply voltage; and
a power-on-reset circuit for the timing controller, the power-on-reset circuit comprising:
a voltage divider powered by the first supply voltage to generate a proportional input voltage;
a bandgap reference circuit powered by the second supply voltage to generate a constant reference voltage; and
a comparator for comparing the proportional input voltage with the constant reference voltage, so as to accordingly output a power-on-reset signal to the timing controller and reset the timing controller when the proportional input voltage exceeds the constant reference voltage.
